(19) United States
(12) Patent Application Publication
(10) Pub. No.: US 2023/0267265 A1
(43) Pub. Date: Aug. 24, 2023

(54) USING MACHINE-TRAINED NETWORK TO PERFORM DRC CHECK

(71) Applicant: D2S, Inc., San Jose, CA (US)

(72) Inventor: Donald Oriordan, Sunnyvale, CA (US)

(21) Appl. No.: 18/097,272

(22) Filed: Jan. 15, 2023

Related U.S. Application Data
(63) Continuation-in-part of application No. 16/949,270, filed on Oct. 22, 2020.
(60) Provisional application No. 63/300,673, filed on Jan. 19, 2022.

(51) Int. Cl. G06F 30/398; G06F 30/27

(52) U.S. Cl. CPC G06F 30/398; G06F 30/27

(57) ABSTRACT

A method for performing pixel-based design rule checking (DRC) is described. This method is used to perform design rule checks for rectilinear and curvilinear designs. In some embodiments, the pixel-based approach is based on computational deep-learning. The pixel-based DRC method of some embodiments is more resilient to false positives than traditional geometric approaches, particularly for designs with curvilinear content, and the inference time remains constant, regardless of how many shapes exist in the design being checked, or how many polygon edges are needed to represent its curvature. The DRC method of some embodiments is implemented by highly parallel architectures (such as Graphics Processing Units (GPU) and Tensor Processing Units (TPU)) to improve processing throughput compared to traditional means.

### BACKGROUND

In electronics engineering, a design rule is a geometric constraint imposed on circuit boards, semiconductor devices, and integrated circuit (IC) designers to ensure their designs function properly, reliably, and can be produced with acceptable yield. Design rules for production are developed by process engineers based on the capability of their manufacturing processes to realize design intent. In Electronic Design Automation (EDA), design rule checking (DRC) checkers are commonly used to ensure that designers do not violate design rules.

DRC is a major step during physical verification signoff on the integrated circuit design, which also involves layout versus schematic (LVS) checks, XOR checks, electrical rule checks (ERC), and antenna checks. The importance of design rules and DRC is greatest for ICs which have nano-scale geometries, and for advanced processes, at smaller geometry process nodes. Variation, edge placement error, and a variety of other issues at new process geometries are forcing IC manufacturers and EDA vendors to confront a growing volume of increasingly complex, and sometimes interconnected design rules to ensure chips are manufacturable.

Equally daunting is the impact of different circuit layout polygons on each other, which has led to significant increases in the number of rules. At the smaller geometry processes (e.g., currently at 28 nanometer (nm) and below) in particular, many IC manufacturers also insist upon the use of more restricted rules to improve yield. All of this has led to a dramatic increase in the number of design rules that have to be checked. The number of rules has increased to the point where it’s no longer possible to manually keep track of all of them, resulting in extreme design rule bloat. This increases the number of required checks, and it makes debugging more difficult. Furthermore, some rules rely on other rules, which is a growing problem for some foundries at some processes.

General-purpose IC design rules have to be somewhat pessimistic/conservative in nature, in order to cater to a wide variety of designs, as it is not known a-priori what polygons will neighbor other polygons during an IC layout, and so the rules have to be able to accommodate just about every possibility.

FIG. 1 illustrates basic design rule checks that involve checking single layer designs, in addition to a multi-layer rule. This figure illustrates two single layer rules, which are a width rule, and a spacing rule, and one multi-layer rule, which is an enclosure rule. In this example, the width rule specifies the minimum width of any shape 105 in the design, and the spacing rule specifies the minimum distance between two adjacent objects (e.g., 105 and 110). These rules will exist for each layer of a semiconductor manufacturing process, with the lowest layers having the smallest rules (typically 30-40 nm) and the highest metal layers having larger rules (perhaps 100 nm). A two-layer rule specifies a relationship that exists between two layers. For example, the enclosure rule illustrated in FIG. 1 specifies that an object of one type, such as a via cut 102 is to be covered, with some additional margin, by a second outer layer such as a metal layer 104.

Traditional DRC uses one-dimensional measurements of features and geometries to determine rule compliance. Checking these rules primarily involves edge processing techniques. Curvilinear designs, and Photonic IC’s (PICs) present new geometric challenges and novel device and routing designs, where non-Manhattan-like shapes such as curves, spikes, and tapers, and shapes running at angles other than 0 degrees and 90 degrees exist intentionally. These shapes expand the complexity of the DRC task, even to the extent that it is impossible to fully describe some physical constraints with traditional one-dimensional DRC rules.

Curvilinear designs are designs that have some amount of curvilinear content, but in some cases are not limited to containing strictly curvilinear shapes only. With curvilinear designs in traditional EDA tools, the curved design layer is fragmented into sets of polygons that approximate the curvilinear shape, which results in some discrepancy from the design intent. The tiniest geometrical discrepancy can generate false DRC errors, which can add up to a huge number, making the design nearly impossible to debug.

It is often the case that although a curvilinear shape is correctly designed, there is a discrepancy in width value between the design layer (off-grid) and the fragmented polygon layer (on-grid), creating a false width error for example. Even though these properly designed structures do not violate manufacturability requirements, they generate a significant number of false DRC errors. Debugging or manually waiving these errors is both time-consuming and prone to human error. Further, the large number of edges that are present in the fragmented polygon sets add a major performance penalty. Hence, in addition to the accuracy/false positive problem, the time taken to evaluate traditional DRC errors on fragmented curvilinear designs, with huge numbers of very tiny edges, becomes prohibitive.

Even with designs containing Manhattan and 45-degree shapes only, when these designs are manufactured, the shapes deposited on the substrate are no longer Manhattan. In other words, the shapes deposited on the substrate during manufacturing become highly curvilinear, due to the realities of manufacturing, particularly at modern process geometries. Proper DRC rule checking requires the DRC processes to account for these curvilinear results.

The running of DRC checks on the manufactured (and hence curvilinear) shapes using traditional DRC checking approaches presents challenges for the reasons outlined above regarding false positives, grid snapping etc. DRC checks are typically run on the Manhattan shapes prior to manufacturing, but in order for the realities of manufacturing to be somehow factored into such checks, the checks themselves have become extremely complex and bloated, run slowly, and are still inaccurate (overly pessimistic).

Some newer techniques (such as equation-based DRC) have arisen to account for the accuracy-related issues in photonics designs. With such techniques, users can query various geometrical properties of the design itself (in addition to the properties of error layers) and perform further manipulations on them with user-defined mathematical expressions. Therefore, in addition to knowing whether a shape passes or fails the DRC rule, users can also determine any error amount, apply tolerance to compensate for grid snapping effects, perform checks with property values, process the data with mathematical expressions, and so on.

While such approaches can certainly improve on the accuracy of traditional techniques, they involve a substantial amount of processing and floating-point operations in particular, meaning that they run extremely slow. Furthermore, they cannot be applied to the shapes that are actually produced by manufacturing, which differ from those drawn in the design due to the realities of manufacturing, limitations due to the laws of physics, etc. The equation-based techniques require access to geometrical parameters which may exist in a photonics design prior to manufacturing, but whose post-manufactured values are certainly not present in the outputs produced by manufacturing process simulation software, hence greatly limiting their applicability.

FIG. 2 illustrates an alternative technique based on the concept of a minimum viable circle that can be manufactured. The minimum viable circle corresponds to the smallest shape that can be reliably printed, taking fundamental process blur into account. Some have proposed a curvilinear Mask Rules Check (MRC) implementation based on the idea of two circles, a smaller circle representing the minimum width/space checks, and a larger circle representing the minimum radius of curvature for the 2D areas.

FIG. 3 illustrates an example of internal width and external space checking. The pair of components 305 on the left side of this figure show internal (width) checking, while the pair of components 310 on the right side of this figure show external (space) checking. Width and space (or bridge and pinch) checks can conceptually be performed by simply sliding the appropriate minimum width circle around each entire polygon. Any places where the circle cannot traverse are violations. As shown, the example fails on the space check as indicated by the darker circle 302. Typically, the minimum width and minimum space will be different sizes, due to print biases as part of the mask manufacturing process.

FIG. 4 illustrates an example of curvature checks that can be performed by sliding circles around the edge of each boundary. Again, if there is any overlap between the circle and the outside of the pattern, the degree of curvature is too large and the pattern is not reliably manufacturable. As shown, the internal curvature is larger than the external curvature, which can happen depending on the resist and etch used in semiconductor manufacturing. However, the overlap of the circle tangential to the curve shows the failure cases which are identified by the arrows 402 and 404.

While the circle sliding approach is at least theoretically viable, there are limitations on design formats which are polygon-based. When checking distances or curvatures with vertices, there will always be some unavoidable overlap and care needs to be taken to implement algorithms that avoid false positives. This is a similar problem as outlined by the concept of user-defined tolerances that were introduced as a workaround. Furthermore, depending on the exact implementation, the ‘sliding’ of the circle may involve a lot of expensive geometric computations to figure out the exact locus over which the centers of the respective circles are to traverse, which may in turn lead to adverse effects on overall performance. While walking a circle around a design shape as described was essentially proposed more as a concept and less perhaps as an actual algorithm, any algorithm that tries to achieve that same conceptual goal while operating in the geometry domain is likely to suffer from similar adverse performance issues.

Both approaches have limitations in terms of false positives, accuracy, and/or performance. Essentially, both of these sets of limitations stem from the need for the algorithms to be applied in the geometric domain using data formats which store data in integral formats (numbers are stored as integer multiples of some fundamental database unit). GDSII and OASIS data formats are heavily used in the EDA and semiconductor manufacturing industries, and store data in such formats. There is clearly a need for an improved approach to design rule checking, that accommodates curvilinear shapes including those produced during manufacturing, and that reduces inaccuracies such as false positives when using integer-based data formats, while running in efficient timeframes.

### SUMMARY

Some embodiments of the invention provide a method for performing pixel-based design rule check (DRC). The method of some embodiments can be used to perform design rule checks for rectilinear and curvilinear designs. The method of some embodiments uses a machine-trained network (e.g., a trained convolutional neural network) to perform the pixel-based processing. In some embodiments, the machine-trained network is trained through a deep learning process that uses data from one or more different DRC methods (such as traditional (geometric), equation-based or circle-tracing methods) to produce the data used for the training.

For example, in some embodiments, the method uses a machine-trained network (e.g., a neural network) that is trained with examples containing rectilinear and curvilinear shapes, some fraction of which have associated DRC errors. The DRC errors for the training data in some embodiments are obtained using traditional geometric methods, equation-based methods, or ‘circle-tracing’ methods. The geometric data representing the shapes to be checked are rasterized to images of a given pixel size. DRC error markers are created where DRC errors exist (as determined by the traditional, equation-based, or circle-tracing methods), and are also rasterized to images of a given pixel size. The input and output raster images are used to train the neural network.

Once trained, the method of some embodiments uses the machine-trained network (e.g., the neural network) to infer DRC errors for rasterized images of designs containing rectilinear and curvilinear content that it has not seen before. The rasterized DRC errors are then converted back to the geometry domain for display in a design editing or viewing tool, for example by overlaying them upon the original design. Some embodiments use a single machine-trained network (e.g., the neural network) that is trained to handle multiple types of DRC at once, while other embodiments use multiple machine-trained networks (e.g., multiple neural networks) to run in parallel, each running as few as one, or perhaps multiple DRC checks.

The machine-trained network in some embodiments employs a deep learning approach to pixel-based, rectilinear and curvilinear rule checking that is both accurate and efficient. The deep learning approach is more resilient to false positives than the geometric approach, particularly for designs with curvilinear content, and the inference time remains constant, regardless of how many shapes exist in the design being checked, or how many polygon edges are needed to represent its curvature. Highly parallel architectures (such as Graphics Processing Units (GPU) and Tensor Processing Units (TPU)) are leveraged in some embodiments to improve processing throughput compared to traditional means.

The preceding Summary is intended to serve as a brief introduction to some embodiments of the invention. It is not meant to be an introduction or overview of all inventive subject matter disclosed in this document. The Detailed Description that follows and the Drawings that are referred to in the Detailed Description will further describe the embodiments described in the Summary as well as other embodiments. Accordingly, to understand all the embodiments described by this document, a full review of the Summary, Detailed Description, the Drawings, and the Claims is needed. Moreover, the claimed subject matters are not to be limited by the illustrative details in the Summary, Detailed Description, and the Drawings.

### BRIEF DESCRIPTION OF FIGURES

The novel features of the invention are set forth in the appended claims. However, for purposes of explanation, several embodiments of the invention are set forth in the following figures.

FIG. 1 illustrates basic design rule checks that involve checking single layer designs, in addition to a multi-layer rule.

FIG. 2 illustrates an alternative technique based on the concept of a minimum viable circle that can be manufactured.

FIG. 3 illustrates an example of internal width and external space checking.

FIG. 4 illustrates an example of curvature checks that can be performed by sliding circles around the edge of each boundary.

FIG. 5 illustrates an overview of a trained neural network receiving images representative of design data and producing the data as output images representative of DRC Violation markers.

FIG. 6 illustrates a process for creating the training data which is then used by the neural network training process.

FIG. 7 illustrates an example of a randomly generated single-layer Manhattan data produced from randomized Manhattan shapes at a high-altitude zoom level.

FIG. 8 illustrates an example of randomized curvilinear shapes at a lower altitude zoom level.

FIG. 9 illustrates an example of a randomly generated multiple-layer Manhattan data at a low altitude zoom level.

FIG. 10 shows an example of a semiconductor stack showing two levels of metal connected by a via, in which metal on Level 1 is connected to the metal on Level 2 by way of a ‘Via’ or ‘cut’.

FIG. 11 illustrates examples of semiconductor shapes showing via cuts with overlapping metal, with the rectilinear cases on top, and the curvilinear cases on the bottom.

FIG. 12 illustrates an example of a randomly generated multiple-layer curvilinear data at a low altitude zoom level.

FIG. 13 illustrates a geometric DRC checker that produces multiple DRC markers in response to receiving the circuit design.

FIG. 14 illustrates an example of a DRC marker created for a single-layer 30 nm min-width violation.

FIG. 15 illustrates an example of a sized-up ground truth DRC marker violation polygon.

FIG. 16 illustrates DRC markers for those portions of a two-layer design which do not satisfy a 20 nm minimum enclosure rule.

FIG. 17 illustrates some examples of DRC markers that escape the filtering net prior to resizing.

FIG. 18 illustrates an example of a first image channel from a tile produced by rasterizing a curvilinear design, representative of an outer layer.

FIG. 19 illustrates an example of a second image channel from a tile produced by rasterizing a curvilinear design, representative of an inner layer.

FIG. 20 illustrates an example of a tile of raster data corresponding to design rule violation markers for a 20 nm minimum enclosure rule.

FIG. 21 illustrates an example of the deep neural network architecture used in some embodiments.

FIG. 22 illustrates a two-layer neural network architecture, with 3 down-sampling operations.

FIG. 23 illustrates an architecture for a neural network with multiple (Nₒ) outputs.

FIG. 24 illustrates a sample loss curve obtained during training.

FIG. 25 illustrates a process for DRC Marker inference via trained neural network.

FIG. 26 illustrates examples of a ground truth and deep learning-inferred DRC marker violations for 100 nm minimum spacing rule.

FIG. 27 illustrates an example of one of the marker locations at a lower altitude zoom level.

FIG. 28 illustrates an example of a ground truth and deep learning-inferred DRC marker violations for 20 nm minimum enclosure rule on curvilinear data obtained from a geometrical layout editing tool.

FIG. 29 illustrates an example of a low altitude, zoomed-in view, containing several ground truth violation markers.

FIG. 30 illustrates an example of a different portion of the design containing both ground truth and deep learning-inferred markers.

FIG. 31 illustrates an example of a portion of the design data with some clusters of geometric engine-produced false positives indicated.

FIG. 32 conceptually illustrates an electronic system with which some embodiments of the invention are implemented.

### DETAILED DESCRIPTION

In the following detailed description of the invention, numerous details, examples, and embodiments of the invention are set forth and described. However, it will be clear and apparent to one skilled in the art that the invention is not limited to the embodiments set forth and that the invention may be practiced without some of the specific details and examples discussed.

Some embodiments of the invention provide a method for performing pixel-based design rule check (DRC). The method of some embodiments is used to perform design rule checks for rectilinear and curvilinear designs. The method of some embodiments uses a machine-trained network (e.g., a trained convolutional neural network) to perform the pixel-based processing. In some embodiments, the machine-trained network is trained through a deep learning process that uses data from one or more different DRC methods (such as traditional (geometric), equation-based or circle-tracing methods) to produce the data used for the training.

Once trained, the method of some embodiments uses the machine-trained network (e.g., the neural network) to infer DRC errors for rasterized images of designs containing rectilinear and curvilinear content that it has not seen before. The rasterized DRC errors are then converted back to the geometry domain for display in a design editing or viewing tool, for example by overlaying them upon the original design. Some embodiments use a single machine-trained network (e.g., the neural network) that is trained to handle multiple types of DRC at once, while other embodiments use multiple machine-trained networks (e.g., multiple neural networks) to run in parallel, each running as few as one, or perhaps multiple DRC checks.

The pixel-based DRC that is performed by the machine-trained networks of some embodiments is more resilient to false positives than the geometric approach, particularly for designs with curvilinear content, and the inference time remains constant, regardless of how many shapes exist in the design being checked, or how many polygon edges are needed to represent its curvature. The inference time (output time) is further enhanced in some embodiments by using highly parallel architectures (such as Graphics Processing Units (GPU) and Tensor Processing Units (TPU)) for the processing of the machine-trained network.

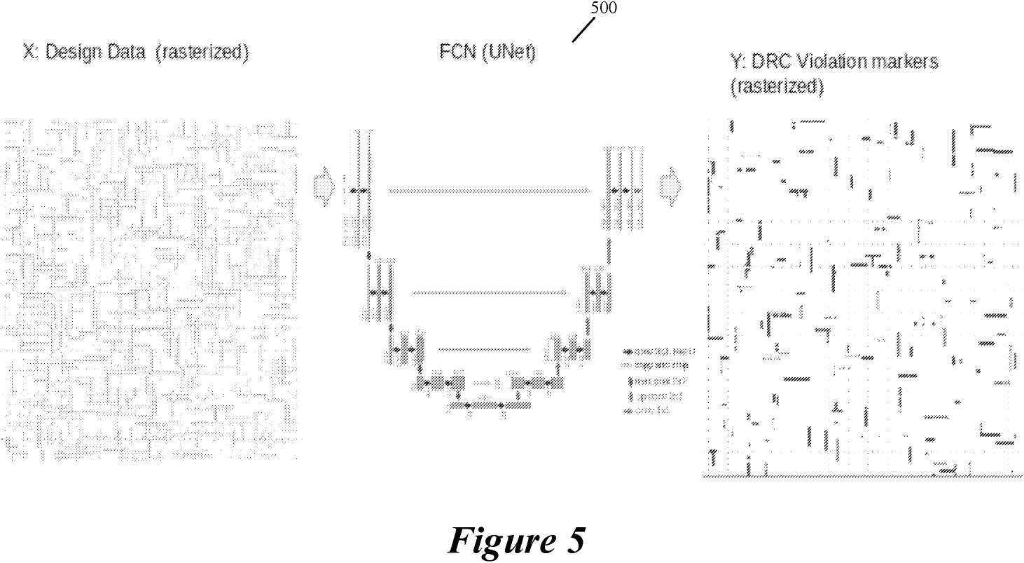

FIG. 5 illustrates an overview of a trained neural network 500 receiving images representative of design data and producing the data as output images representative of DRC Violation markers. The neural network 500 is trained with image examples containing rectilinear and curvilinear shapes, some fraction of which have associated DRC errors. The DRC errors for the training data in some embodiments are obtained using traditional geometric methods, equation-based methods, or ‘circle-tracing’ methods, or any other method. The geometric data representing the shapes to be checked are rasterized to images of a given pixel size.

Rasterization is the task of taking an image in which shapes or their contours are defined in one format (e.g., in a vector graphics format) and converting the image into a raster image in which each shape or its contours is/are defined by reference to a series of pixels, dots or lines, which, when displayed together, create the image that was originally represented by the shapes. In some embodiments, the rasterized images are defined in terms of pixels that are displayed on a computer display, video display or printer, or stored in a bitmap file format. As such, rasterization in some embodiments refers to the technique of drawing 3D models, or the conversion of 2D rendering primitives (such as polygons, line segments, etc.) into a rasterized format (e.g., into a pixel-based definition of those models or primitives).

In some embodiments, DRC error markers are created where DRC errors exist (as determined by traditional methods) and are rasterized to images of a given pixel size. The input and output raster images are then used to train the neural network. Once trained, the neural network is used to infer DRC errors for rasterized images of designs containing rectilinear and curvilinear content that it has not seen before. The rasterized DRC errors are then converted back to the geometry domain via a contouring operation. This step allows the visualization or display of the DRC error markers in a geometry-based design editing or viewing tool, for example by overlaying them upon the original design. In some embodiments, the ‘marching squares’ process (e.g., marching-square algorithm) is used during contouring to achieve this transformation.

In some embodiments, the overall process involves a rasterization step to move from the geometry domain to the pixel domain. This rasterization step does have some associated cost. Hence, it is beneficial to operate as much in the pixel domain as possible thereafter. This allows the cost of rasterization to be amortized over other operations performed within the pixel domain, and the entire flow benefits significantly from pixel-friendly hardware architectures such as GPUs and TPUs. Some embodiments provide a method for performing DRC operations in the pixel space using deep learning. Also, some embodiments augment the deep learning approach with other pixel-based approaches, creating a hybrid method. For example, the DRC rule checks in some embodiments are fully or partially implemented using a deep learning approach, while others are fully or partially implemented by other pixel-based approaches (such as by using standard image-processing programs) which are not deep-learning based.

In some embodiments, deep learning-based approaches are augmented by other pixel-based methods such as filtering, or morphological image processing methods. High-pass filtering is used to enhance rapidly changing areas of the image most often associated with the edges of the image (such as the edges of the post-rasterized polygons). Morphological image processing includes dilation and erosion where dilation operation adds pixels to the boundaries of the object in an image, and erosion operation removes the pixels from the object boundaries. Morphological image processing events in some embodiments are used to dilate objects within the image until they touch, at which point if the number of dilation steps exceeds a certain minimum, the objects within the image are deemed as having insufficient spacing.

GPUs and TPUs utilize highly parallel architectures. While a CPU is excellent at handling one set of very complex instructions, a GPU or TPU is very good at handling many sets of very simple instructions, such as those related to neural network processing. Pixel-based methods such as neural networks therefore advantageously use the high degree of parallelism present in GPU and TPU devices to perform their processing rapidly, and are used in some embodiments to accelerate curvilinear design rule checking operations.

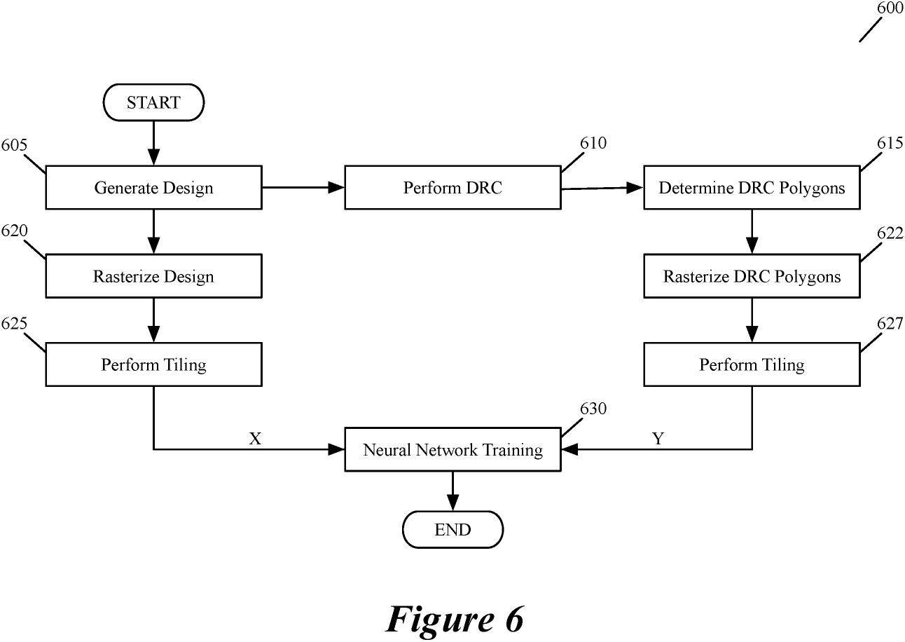

FIG. 6 illustrates a process 600 for creating the training data and then using this training data to train a neural network. The process generates multiple known inputs X in a design (e.g., input patterns from the design) with multiple known outputs Y (e.g., DRC polygons associated with DRC violations). The process 600 starts by generating, or selecting a previously generated, (at 605) IC design. The IC design in some embodiments includes a single IC layer, for single-layer DRC rules (such as min-width, min-spacing), or multiple IC layers (e.g., multiple interconnect or wiring layers) for multiple-layer DRC rules (such as min-enclosure).

After 605, the process 600 forks into two sub-processes. The first sub-process includes operations 620 and 625 that generate known inputs X for neural network training at 630. The second sub-process includes operations 615, 622 and 627 for generating several known outputs Y each associated with a known input X. Specifically, at 610, the process 600 performs a DRC check operation on the generated design. This DRC check operation in some embodiments uses a known DRC techniques, such as a traditional geometric means, equation-based means, circle tracing, or any other means.

The process 600 then identifies (at 615) output polygons produced by DRC checks. Both the original design and the DRC polygons are rasterized (at 620 and 622, respectively) to images. The process 600 then groups (at 625 and 627, respectively) the rasterized image of the design and the DRC polygons into tiles, which correspond to smaller portions of the overall IC design. Splitting the IC design into smaller pieces is advantageous as these smaller designs are more suitable for processing (at 630) by the neural network. Some embodiments perform the process 600 as many times as needed for as many IC designs as needed in order to sufficiently train the neural network. In some embodiments, the neural network is trained using the information from just one design, while in other embodiments, the neural network is trained by using information from multiple designs. After 630, the process 600 ends.

The collected tiles in some embodiments are stored on a disk as individual image files, or in a database, or any other appropriate form for neural network training. When the design contains multiple design layers, each layer is rasterized individually in some embodiments. The resulting single-layer raster images in some embodiments are stored separately, or combined into multiple-channel raster images and essentially stored together in other embodiments. As shown in FIG. 6, the rasterized, tiled design images entering the Neural Network Training operation at 630 from the left are referred to as X data (known input data), while their corresponding rasterized, tiled DRC polygon images entering from the right are referred to as Y data (known output data).

To train the neural network, some embodiments feed each known input (a rasterized input pattern from the X data) through the neural network to produce a predicted output Y′, and then compare this predicted output Y′ to the known output Y (e.g., DRC polygon) of the input to computer a set of one or more error values (e.g., compute a difference value based on the difference between the known output and the predicted output). The error values for a group of known inputs/outputs are then used to compute a loss function (such as a cross-entropy loss function described below), which is then back propagated through the neural network to train the configurable parameters (e.g., the weight values) of the neural network. Once trained by processing a large number of known inputs/outputs, the trained neural network can then be used (as described above by reference to FIG. 5) to perform DRC operations to identify DRC violations in IC designs that the neural network processes.

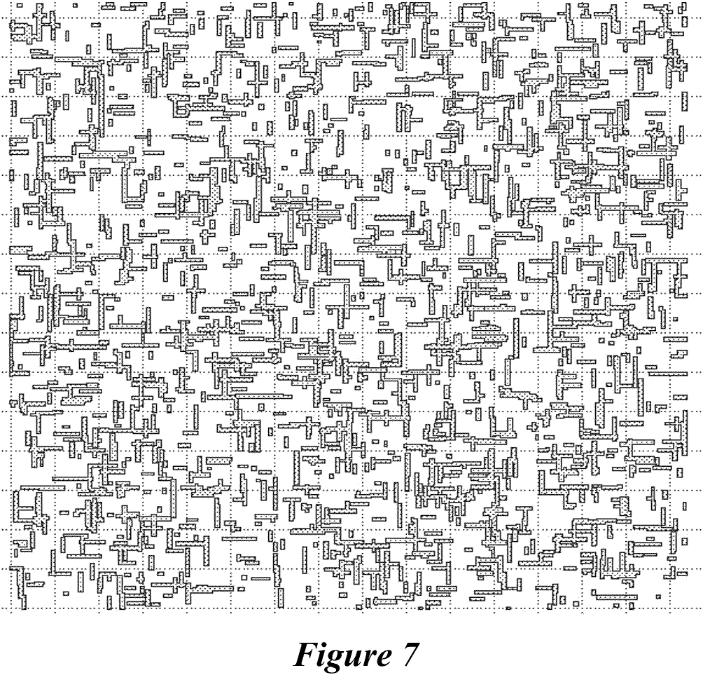

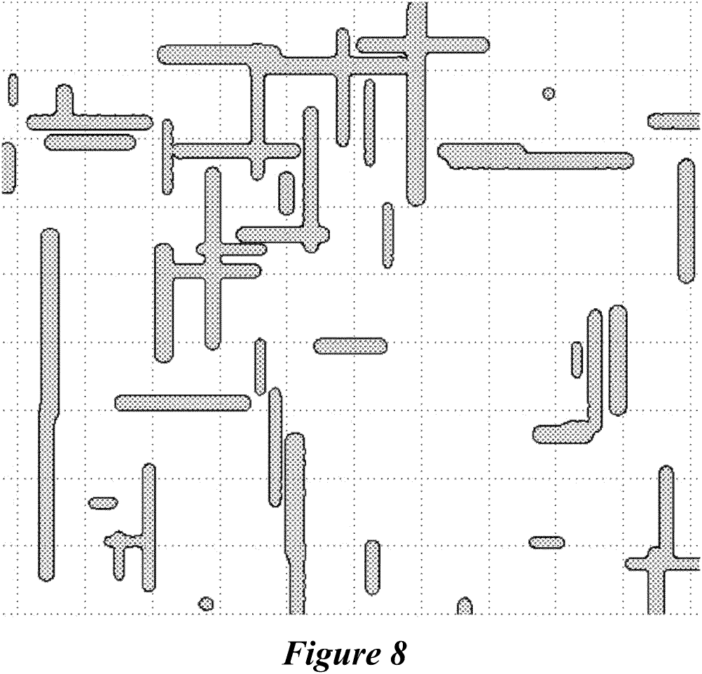

In some embodiments, single layer design data ‘X’ are produced from randomly generated Manhattan and/or diagonal shapes of various dimensions and at various locations. FIG. 7 illustrates an example of a randomly generated single-layer Manhattan data produced from randomized Manhattan shapes at a high-altitude zoom level. Single layer design data ‘X’ in some embodiments are produced from randomly generated shapes, including rectilinear and curvilinear shapes, of various dimensions and at various locations. FIG. 8 illustrates an example of randomized curvilinear shapes at a lower altitude zoom level. Various methods in some embodiments are used to generate the curvilinear shapes.

In some embodiments, curvilinear data are generated from rectilinear/Manhattan and/or diagonally generated data by applying different transformations. Manufacturing process simulation software in some embodiments is used to achieve the transformation, where for example, the input data to the simulators represent a set of Manhattan, rectilinear, and/or diagonal shapes which are to be manufactured using a semiconductor manufacturing process, and the output shapes produced by the software are the corresponding shapes that are expected to be manufactured, given the limitations of the manufacturing process. In other embodiments, a (different) appropriately trained neural network is used to determine the transformation to curvilinear shapes. For example, when the curvilinear shapes represent the outputs of a semiconductor manufacturing process, the trained neural network disclosed in U.S. Pat. Application No. 16/949,270, now published as U.S. Pat. Publication 2022/0128899 is used in some embodiments to determine the curvilinear shapes.

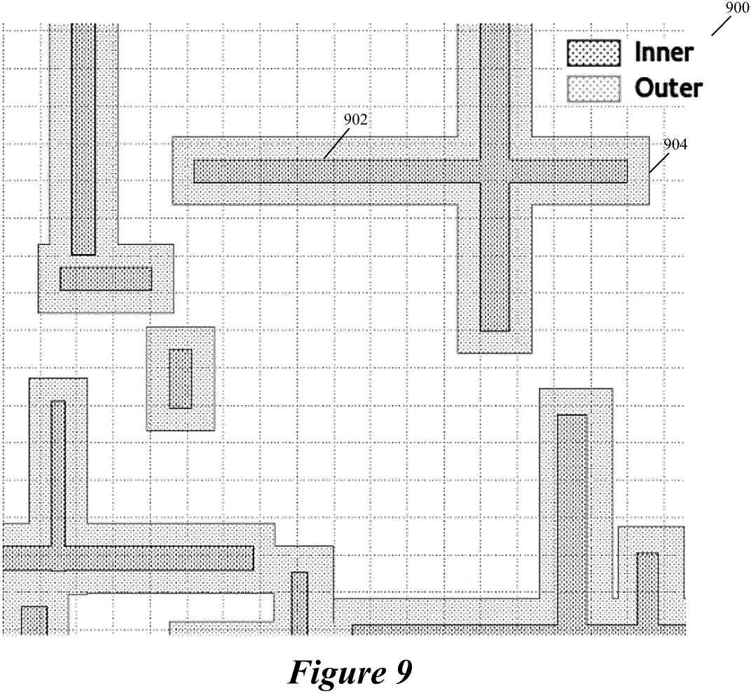

For multiple-layer DRC rules, multiple-layer design data ‘X’ in some embodiments are also produced from randomly generated Manhattan and/or diagonal shapes of various dimensions and at various locations. FIG. 9 illustrates an example of a randomly generated multiple-layer Manhattan data 900 at a low altitude zoom level. Here, the layer containing the dark data represents an ‘inner’ layer 902, and the layer containing the lighter data represents an ‘outer’ layer 904, which according to the design rule needs to enclose the ‘inner’ layer shapes by a minimal enclosure amount. Such rules are common due to alignment problems in manufacturing, when it is difficult to accurately align the ‘outer’ layer 904 with the ‘inner’ layer 902 during manufacturing (especially when the inner and outer layers are created in separate steps), and yet a complete overlap is required.

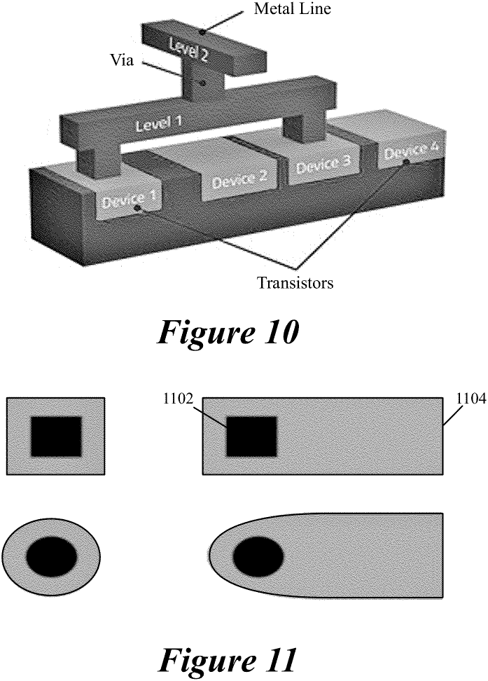

An application in semiconductor manufacturing corresponds to the manufacturing of metal shapes which need to fully enclose a via cut layer, when transitioning a conductor from one metal layer to another. FIG. 10 shows an example of a semiconductor stack showing two levels of metal connected by a via, in which metal on Level 1 is connected to the metal on Level 2 by way of a ‘Via’ or ‘cut’. Design rules often require that the cross section of the top/bottom of the via/cut needs to be enclosed by a corresponding cross section of the metal on the layers above/below by some minimum amount, so as to ensure full contact of the via cut by the metal above/below even when the alignment of the metal and the via cut isn’t 100% perfect during manufacturing.

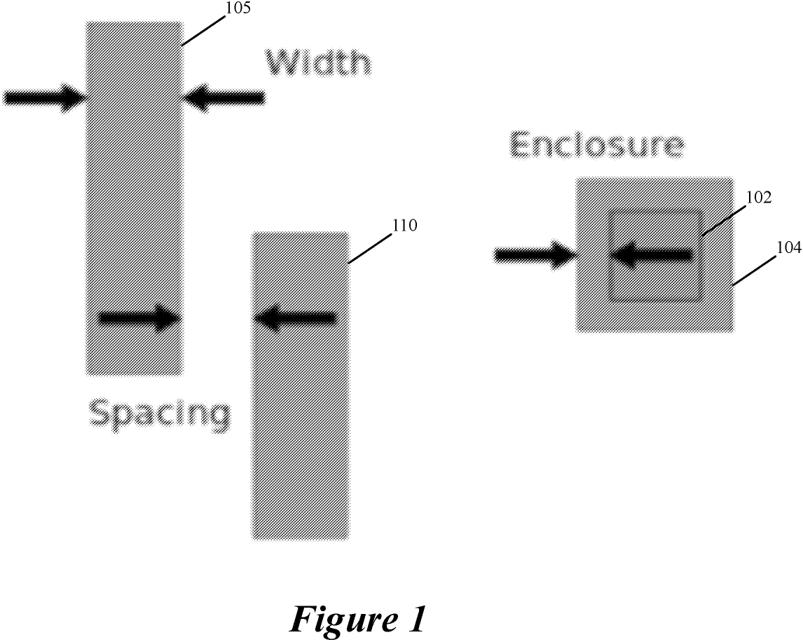

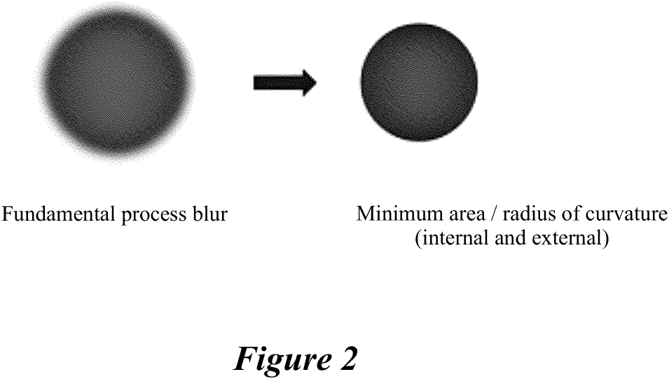

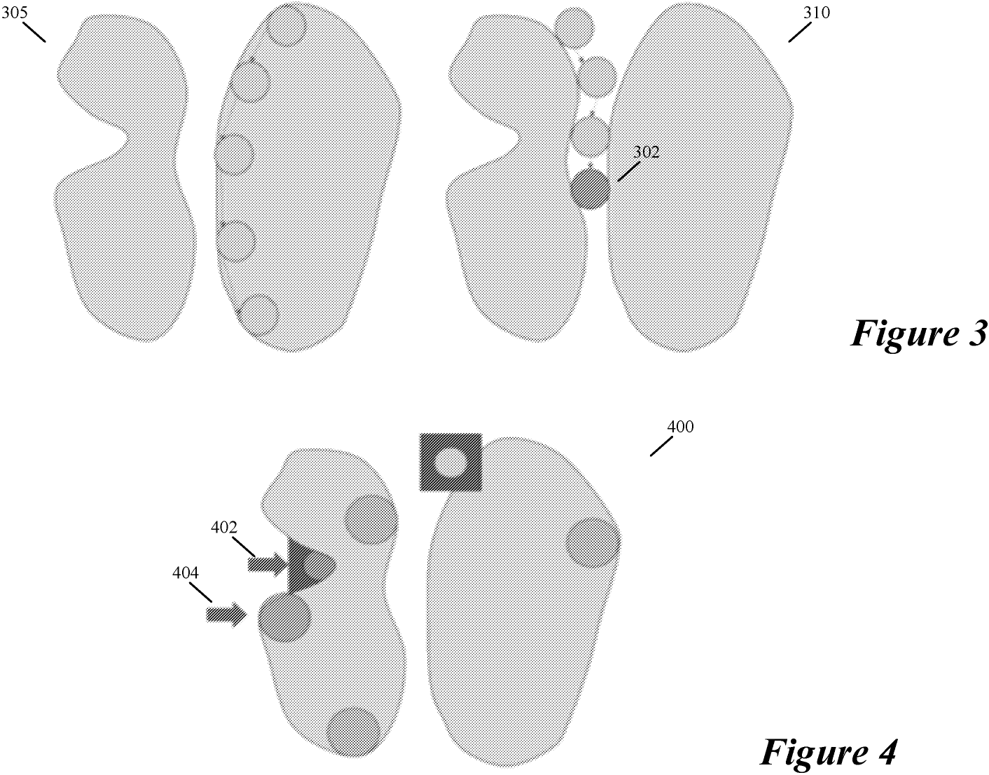

It is common in rectilinear semiconductor designs for via cut shapes to be a square 102 as shown in FIG. 1. For curvilinear designs, it is more common in some embodiments for the via to be a circle or oval shape, along with the corresponding portion of the metal ‘outer’ shape which is to overlap it by some minimum amount.

FIG. 11 illustrates examples of semiconductor shapes showing via cuts 1102 (e.g., displayed in black) with overlapping metal 1104 (e.g., displayed in grey), with the rectilinear cases on top, and the curvilinear cases on the bottom. In both cases, the darker areas represent the via cut, while the lighter colored grey areas represent the metal which needs to overlap the via cut by some minimum enclosure amount.

While designed rectilinear vias in semiconductor devices will tend to be square or rectangular in shape, some embodiments are not limited to these shapes only. Instead, some embodiments generate multiple layer data with a variety of shapes to expose the neural network to a variety of such shapes during training, in order to allow the trained network to generalize better, and to allow it to be used in other problem domains in which more complex multiple-layer curvilinear shapes are encountered.

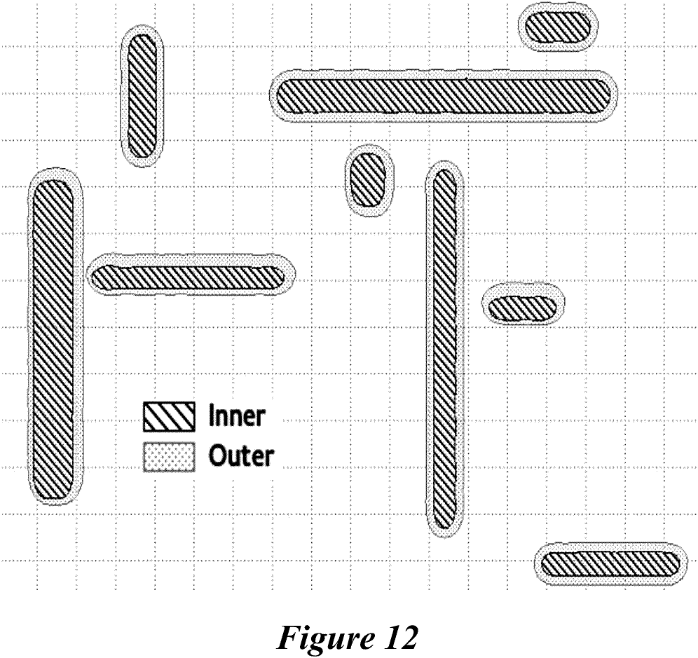

FIG. 12 illustrates an example of a randomly generated multiple-layer curvilinear data at a low altitude zoom level. As shown, some of the darker (inner) layer shapes are centered within the lighter (outer) layer shapes, while others are clearly offset, i.e., not centered. The shapes with the larger offsets will tend to produce more min-enclosure DRC violations.

Labeled data ‘Y’ corresponding to DRC violation markers in some embodiments are produced from the inputs ‘X’ by way of a DRC checking step. Any DRC mechanism such as traditional geometry-based DRC checking, equation-based checking, or the circle-tracing methods discussed previously may be used.

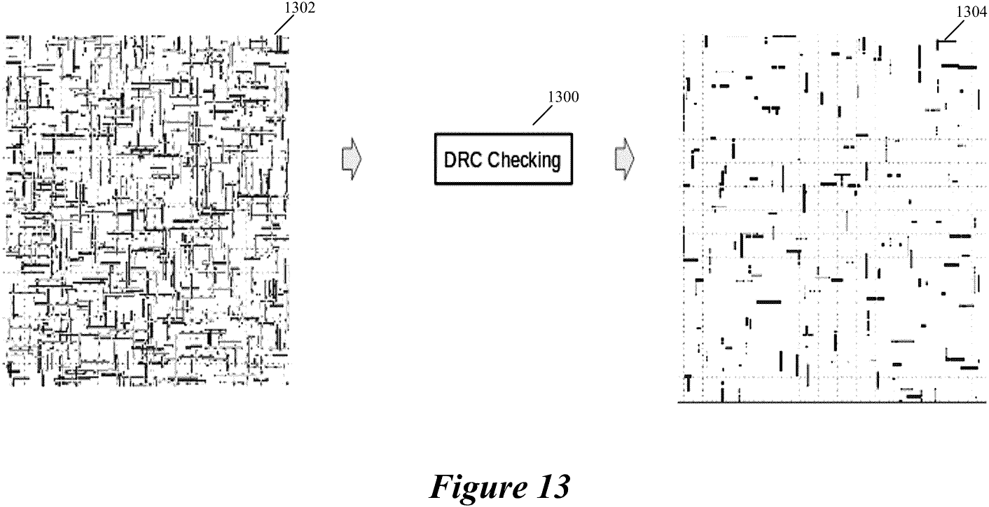

FIG. 13 illustrates a geometric DRC checker 1300 that produces multiple DRC markers 1304 (displayed in a first color, e.g., dark blue) to the right of the figure, in response to receiving the circuit design 1302 (displayed in a second color, e.g., yellow) to the left. The DRC markers in some embodiments are placed in locations so as to highlight one or more edges of the input design which are involved in the DRC violations.

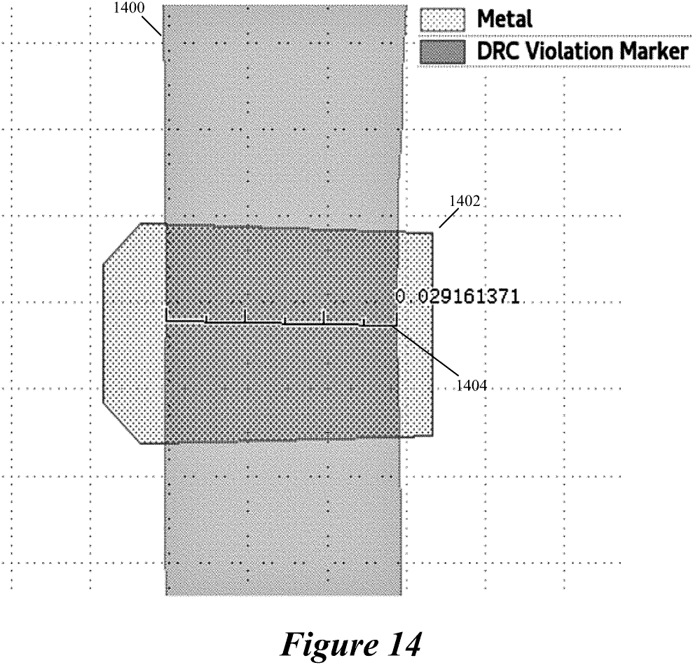

FIG. 14 illustrates an example of a DRC marker created for a single-layer 30 nm min-width violation. As shown, a marker polygon 1402 (displayed in a first color, e.g., dark blue) has been created for the portion of a colored design 1400 (e.g., a light, yellow-colored design) that is found to be narrower than the design rule value of 30 nm. In this case, the DRC violation marker is placed around both left and right edges of the curvilinear design portion where the width is less than 30 nm. To aid in the visualization, a ruler 1404 has also been placed in this image showing the design polygon width is closer to 0.029 um (micrometers) than the desired 30 nm value, in the region of the marker. Other portions of the polygon 1402 towards the top and bottom of the image 1400, which are clearly wider than the 29 nm pinch point, are not covered by a DRC marker.

As noted previously, ‘false positive’ DRC markers in some embodiments are inadvertently created when performing DRC checks upon certain designs, particularly those with curvilinear content. This is largely due to the ‘snapping’ of geometric coordinates to a grid system, common in state-of-the-art geometry editing tools such as a circuit design layout editor. FIG. 14 indicates such a grid. Snapping grids in some embodiments are finer than those shown in the image, but commonly exist for designs which are stored in the industry-standard GDSII and OASIS formats. The snapping effect introduces precision errors in the DRC checking system, which are then translated to false positives, often manifesting as very small DRC violation markers. In some embodiments, very small DRC markers such as these are filtered out prior to subsequent processing. Even if the filtering isn’t sufficiently precise to remove all such very small markers, and a few escapes are present after filtering, this generally is not a problem for the deep learning algorithm.

In some embodiments, DRC markers (which survive the filtering step above) are created with at least a minimum size to facilitate their rasterization and learning during neural network training. In other embodiments, DRC markers are intentionally oversized to achieve the same goal. For example, the DRC marker polygons are oversized by one pixel dimension value in each edge, where the pixel dimension corresponds to the pixel dimension used when subsequently rasterizing the images. A pixel size of 8 nm in some embodiments is used during rasterization, hence the oversizing amount is 8 nm for each edge of the DRC marker polygons. Other oversize amounts are used without departing from the spirit of some embodiments of the invention. One reason for oversizing the DRC markers is to ensure that they are still clearly present after rasterization, i.e., clearly visible in the rasterized images. For example, in some embodiments, DRC marker polygons that are sub-pixel in dimension (e.g., a small 5x6 nm DRC marker) are not particularly visible in grey-scaled rasterized images if larger pixels sizes (such as 8x8 nm) are used in the rasterization process. The DRC markers so-produced in this process are referenced as ‘ground truth’ in this document.

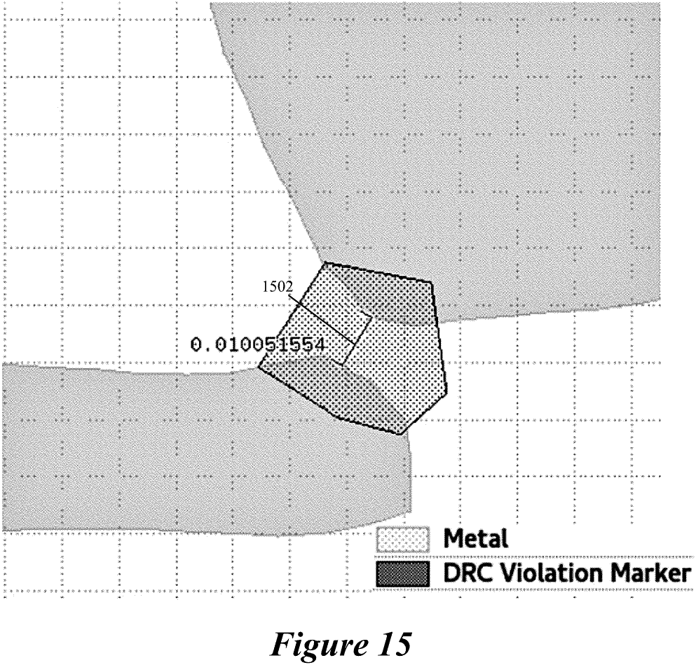

FIG. 15 illustrates an example of a sized-up ground truth DRC marker violation polygon. A minimum spacing violation between two curvilinear shapes is shown, along with a ruler 1502 to give a sense of scale. As shown, the original (un-resized) DRC marker polygon sits in the space between the two curvilinear shapes, but it has been expanded a little (8 nm per edge) in order to facilitate its rasterization and learning. As a result, the expanded/resized marker polygon also encompasses some of the edges of the shapes involved in the violation.

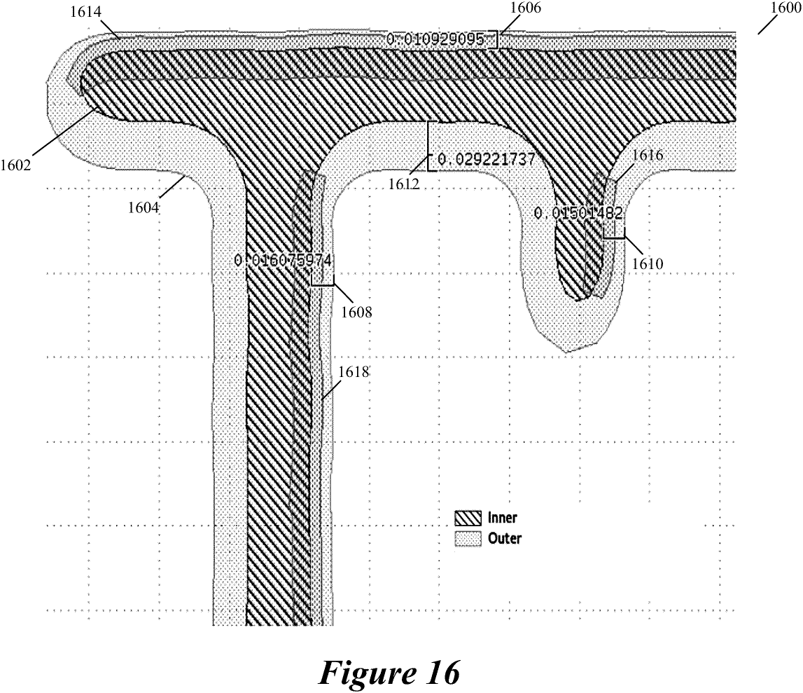

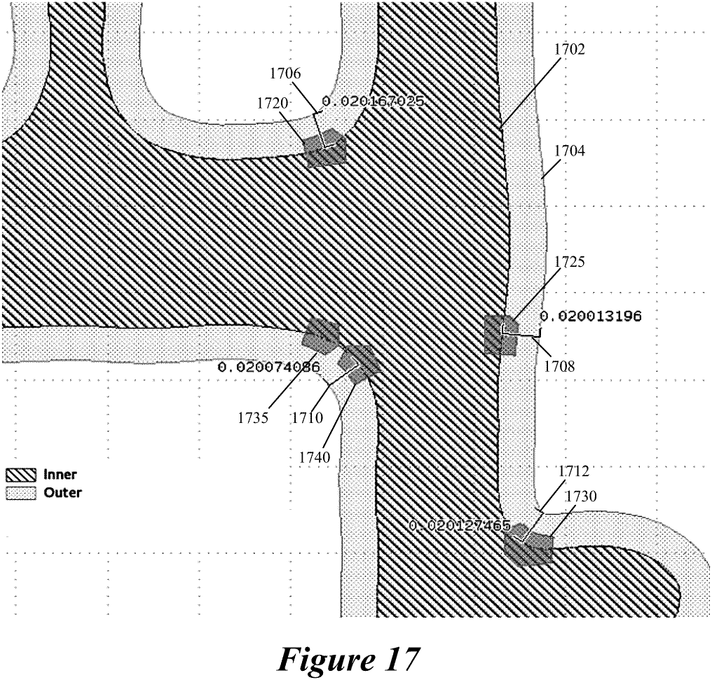

FIG. 16 illustrates DRC markers for those portions of a two-layer design which do not satisfy a 20 nm minimum enclosure rule. These figures contain two layers, an inner layer 1602 displayed in a first color (e.g., a darker color) with left-to-right cross hatching, and an outer layer 1604 displayed in a second color (e.g., a lighter color). The outer layer 1604 is expected to enclose the inner layer 1602 shapes by a minimum of 20 nm. Some areas are marked by shapes 1614-1618 to identify areas of DRC violations. These shapes 1614-1618 are displayed in a third color. Rulers 1606-1612 have been added to illustrate these violations.

FIG. 17 illustrates some examples of DRC markers that escape the filtering net prior to resizing. This figure also contains two layers, an inner, darker layer 1702 with left-to-right cross hatching, and an outer, lighter layer 1704. Again, the outer layer 1704 is expected to enclose the inner layer 1702 shapes by a minimum of 20 nm. Some very small violations 1720-1740 are shown, however, which upon closer inspection are not really violations at all. As shown, rulers 1706-1712 have been placed indicating that the enclosure amounts are marginally larger than the minimum required value of 20 nm, however, grid snapping during DRC processing resulted in some very tiny violation markers at these locations that managed to escape attempts to identify and filter them. These markers were then sized up by one pixel dimension (8 nm) along each edge, and so appear within the ground truth marker image as shown. It is an objective that such ‘false positive’ markers do not appear (or at least minimally appear) in the output produced by the neural network.

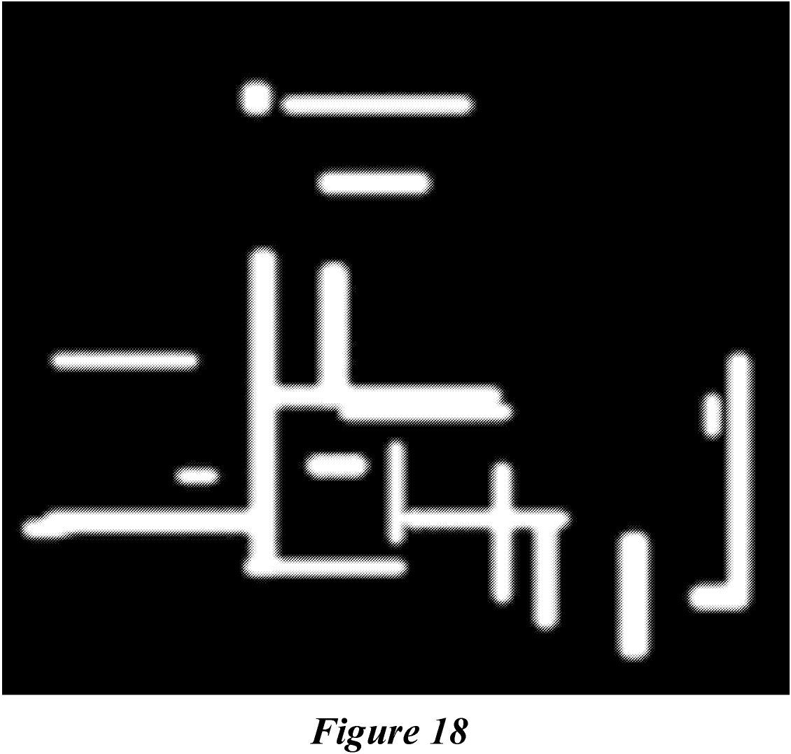

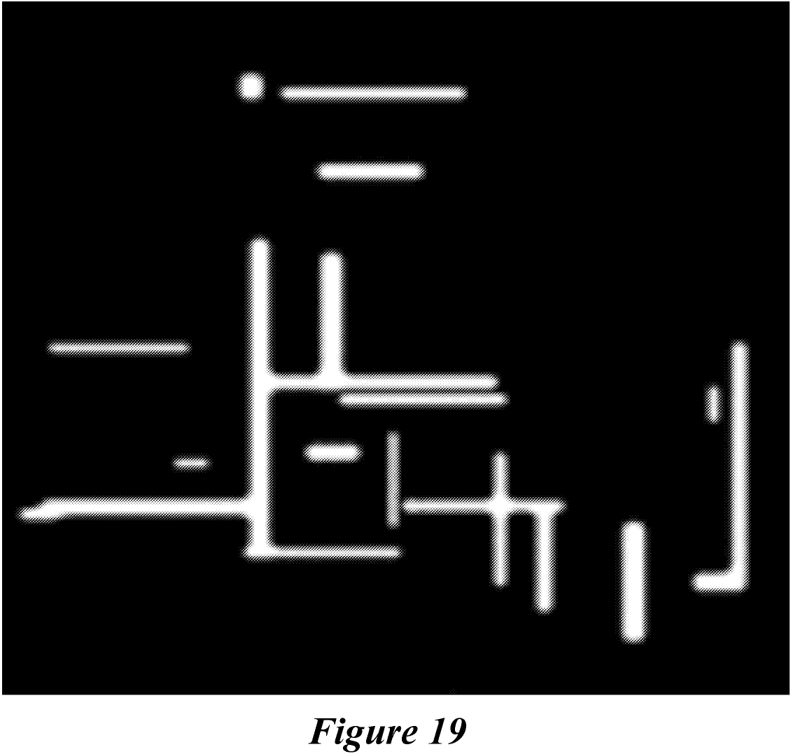

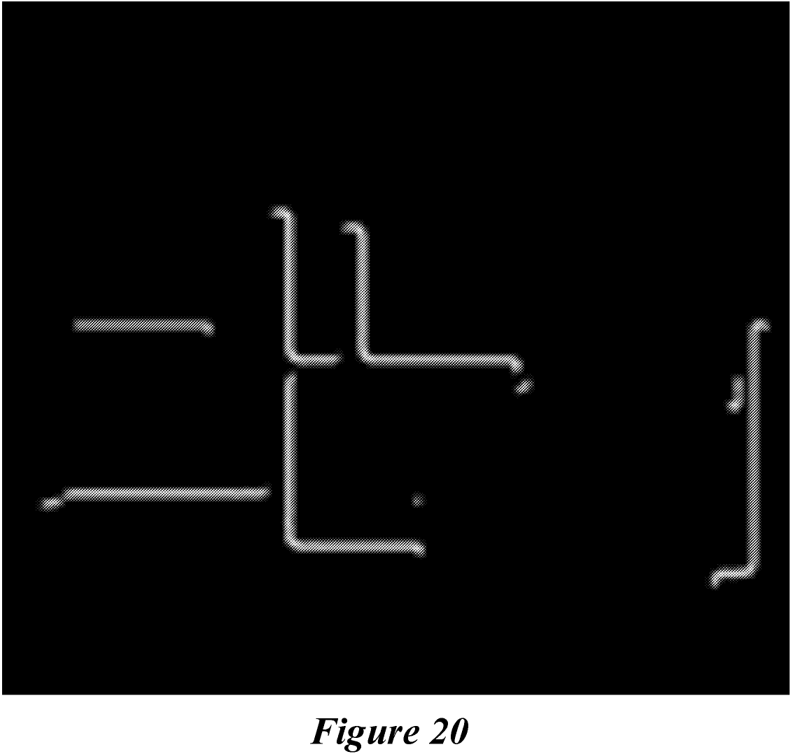

FIG. 18 illustrates an example of a first image channel from a tile produced by rasterizing a curvilinear design, representative of an outer layer. The non-black portions correspond to the outer layer in the corresponding geometrical design data. FIG. 19 illustrates an example of a second image channel from a tile produced by rasterizing a curvilinear design, representative of an inner layer. The non-black portions correspond to the inner layer in the corresponding geometrical design data. FIG. 20 illustrates an example of a tile of raster data corresponding to design rule violation markers for a 20 nm-minimum enclosure rule. The non-black portions correspond to those locations where the outer layer fails to enclose the inner layer by 20 nm.

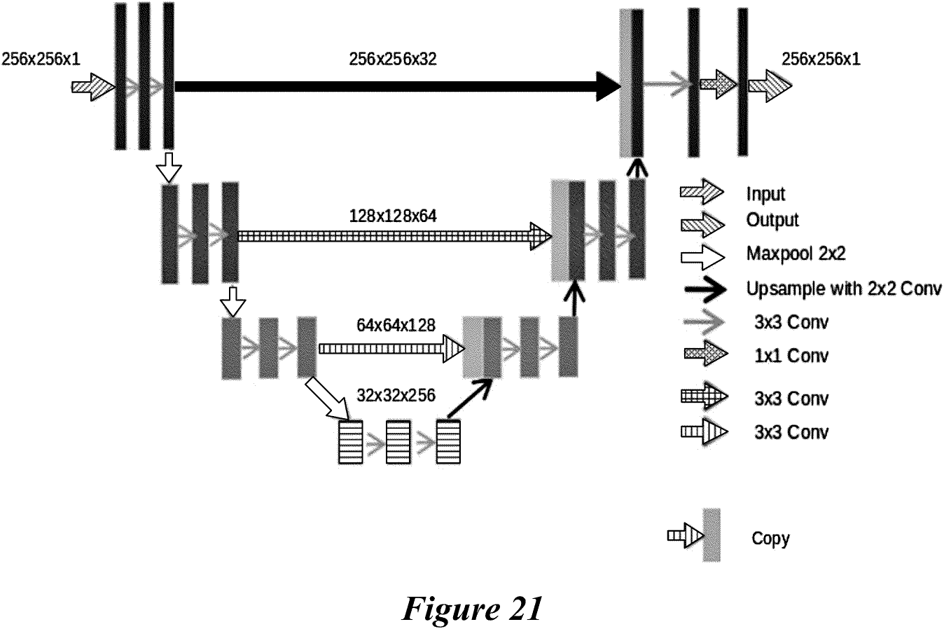

FIG. 21 illustrates an example of the deep neural network architecture used in some embodiments. This example corresponds to a single-layer DRC rule, for which the input is a tile of 256x256 pixels, containing a single input channel. The output is likewise a single channel image of dimension 256x256. The arrows represent Tensor operations such as 3x3 convolution, 1x1 convolution, downsampling via 2x2 maxpool operations, and upsampling operations, which are familiar to those skilled in the art of deep convolutional neural networks.

This architecture modifies the U-Net architecture (used for biomedical image segmentation) in several ways. First, the input images are 256x256 in the height and width dimension, unlike those of 572x572 in size. Likewise, the output image dimensions are 256x256, rather than those of 388x388. This is due to the use of padded convolutional operations, as opposed to the un-padded operations. Furthermore, the network comprises three down-sampling steps only, compared with 4. Another change is that the initial set of convolution operations use a filter depth of 32, unlike the 64. These changes allow the network to be much smaller in terms of its number of trainable parameters, and still produce outputs (DRC markers) which are sufficiently accurate. As a result, the network is also faster to train and faster to evaluate.

Finally, the output layer is very different. Rather than using a softmax activation function output in combination with a cross entropy-based loss function, in some embodiments, a linear activation function output is used in combination with mean-squared error loss function. The output produced by the original U-Net is essentially a Boolean output per-pixel (each pixel is either fully part of a segmentation class or it is not), whereas the network in some embodiments of the present invention acts as a regression application, predicting pixel values that lie anywhere between 0.0 and 1.0 per pixel. The regression application approach allows for more fine-grained accuracy in computing the contours later (the contours are not snapped to pixel edges), and also tends to suffer less from issues with learning/predicting DRC markers which are as small as 1 pixel (8 nm) per side.

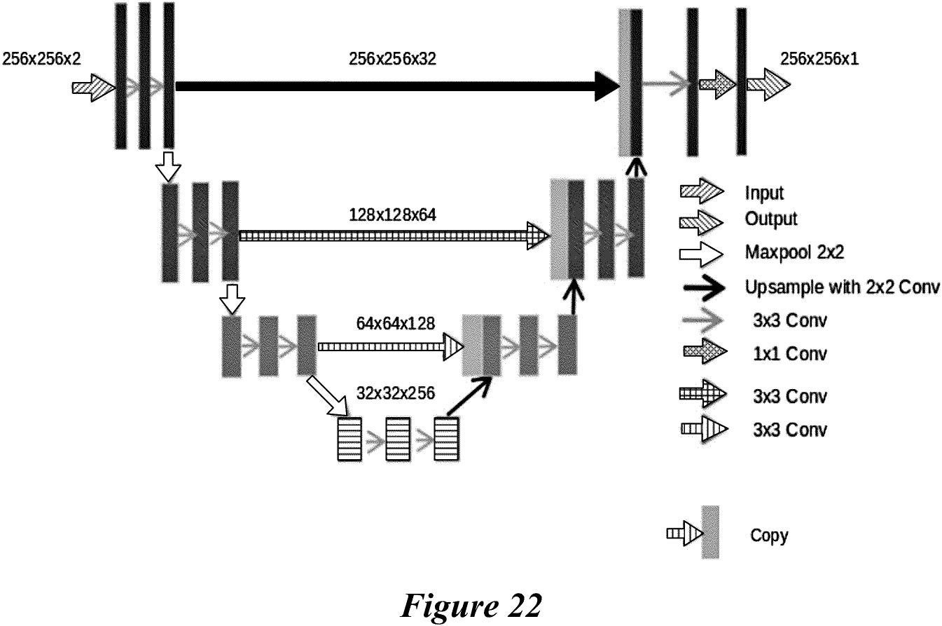

For multiple-layer DRC rules, the number of channels is expanded in the input image. For a minimum-enclosure rule, which involves two layers, the input tiles are 256x256x2 (using a channels-last representation), which has two channels (for example, one channel for the inner layer, and one for the outer layer). FIG. 22 illustrates a two-layer neural network architecture, with 3 down-sampling operations. More complex rules involving additional layers in some embodiments are covered by adding appropriate extra channels to the input image.

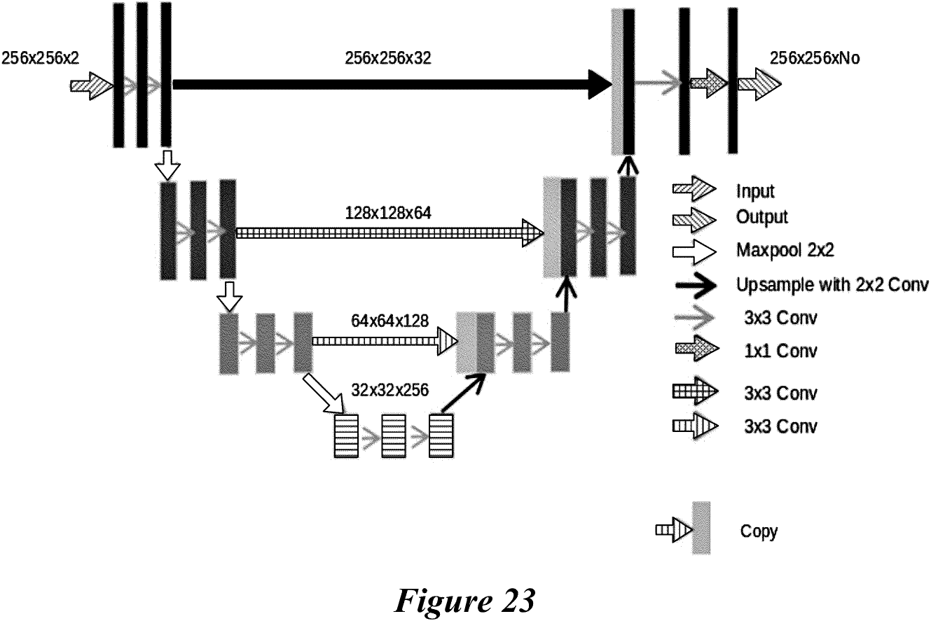

In some embodiments, a dedicated neural network is assigned to each type of DRC rule. If there are N DRC rules, then there are N dedicated neural networks, each with its own individual set of weights learned during training. In other embodiments, a single neural network is used for processing multiple DRC rules at once, by adding additional output channels. FIG. 23 illustrates an architecture for a neural network with multiple (Nₒ) outputs. In this case, the final output convolution layer is configured to use ‘Nₒ’ filters rather than a single filter, where Nₒ is the required number of outputs. The output image is correspondingly a Nₒ-channel image. In alternative embodiments, multiple neural networks are used, with each configured to process a different subset of the total number of DRC rules.

In some embodiments, the output(s) produced by the neural network are considered as surfaces (like mountain ranges), with peaks (mountain tops) corresponding to DRC violation marker locations. This is achieved by using a linear output activation function, as opposed to the sigmoid activation function used by the original biomedical U-Net application. Contour operations in some embodiments are used to convert the surface peak images produced by the trained neural network into DRC marker polygons in geometric form, which are then readily viewed in geometry-based design editing tools such as integrated circuit layout editors, etc.

Many thousands of data sample (X, Y) tile pairs are generated using the system discussed previously in order to train the neural network. These tiles in some embodiments are split into multiple databases, with a large portion (e.g. 80%) of the tiles being saved to a ‘training’ database, and a smaller portion (e.g. 15%) stored to a ‘validation’ database. The remaining portion (e.g. 5%) in some embodiments is stored in a test database. In some embodiments, a HDF5 file format is used to store this database, though other file/database formats could be used without departing from the spirit of the art. The training database examples are used to teach the network about the relationship between X (design data layers, rasterized) and Y (DRC violation markers, rasterized), using standard techniques familiar to those skilled in the art of deep learning. The examples from the validation database in some embodiments are used to evaluate the progress of the training. The “training” data set is the general term for the samples used to create and tune the model, while the “validation” data set is used to qualify performance.

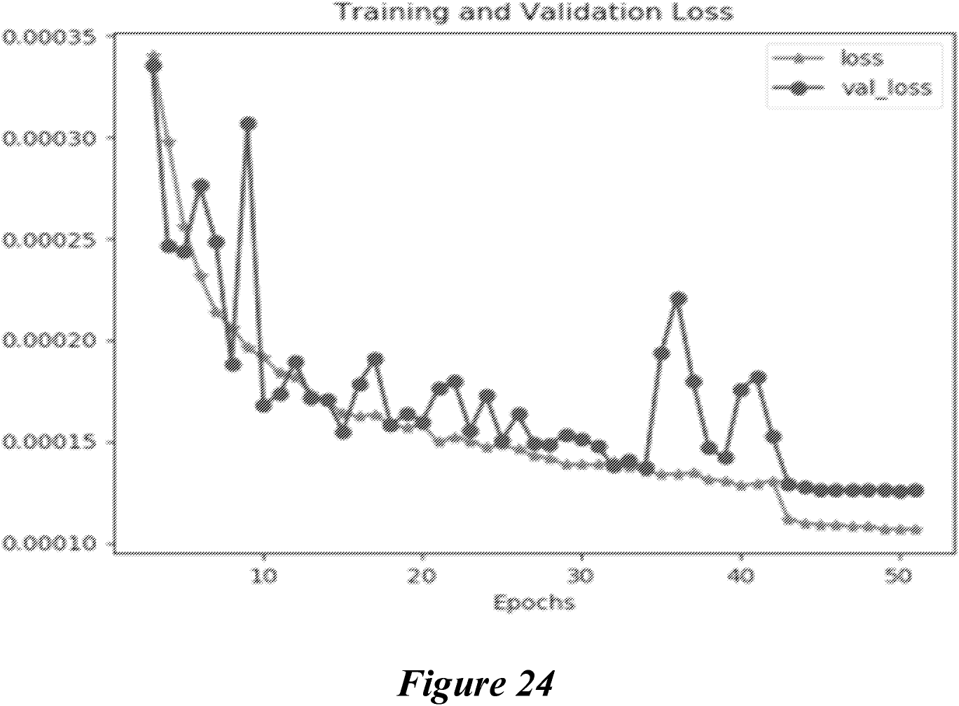

FIG. 24 illustrates a sample loss curve obtained during training. The loss is the mean-squared error between the network-predicted DRC violation marker surface and the ground truth DRC violation marker surface. Two curves are shown, one showing the loss with respect to the training data (e.g., star symbols), and one showing the loss with respect to the validation data (e.g., circle symbols). After a number of training epochs (in which the network is exposed to the training data over and over), both losses reduce to small values (i.e., the predicted values converge to be close to the ground truth values), with the validation loss eventually flattening out as the network converges and the model begins to overfit to the training data. In this particular example, the learning rate for the network was additionally reduced by one order of magnitude (from 1e-3 to 1e-4) after ~42 epochs, with the smaller rate used to fine tune the network toward the end of training.

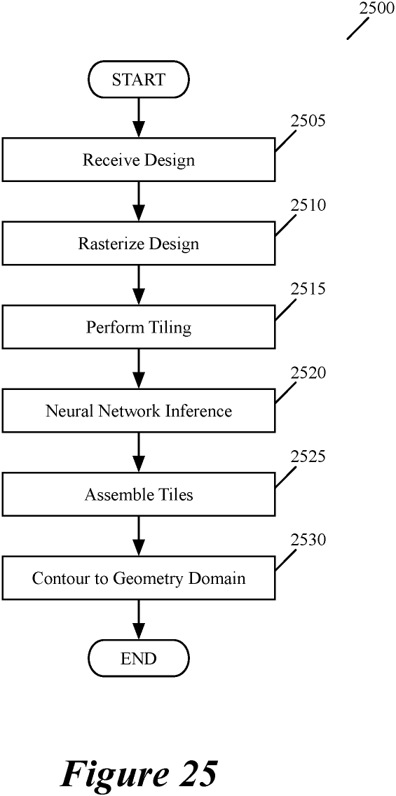

FIG. 25 illustrates a process 2500 for DRC marker inference via trained neural network. After the network has been trained, the process 2500 for inference of DRC violation markers for new, previously unseen designs, is shown. In some embodiments, the process 2500 receives the design (at 2505), which contains one or more design layers which are to be checked. The process 2500 then rasterizes (at 2510) the design as previously described and splits the design (at 2515) into 256×256 pixel image tiles. The tiles are then presented (at 2520) to the trained neural network, which quickly infers/predicts a DRC violation marker surface for each tile. The process 2500 assembles (at 2525) the output tiles into a full surface, which in some embodiments are then contoured (at 2530) from the raster domain back into the geometry domain for display in geometry-based tools. After 2530, the process 2500 ends. During training, the network learns to essentially ignore the seemingly randomly placed and very small DRC markers which escape the filter described above with respect to the generation of the training data. Only markers which reliably appear (with respect to the geometry of the input data) are effectively learned by the network. False positive markers are essentially treated as noise in the data. Hence, the network learns to automatically remove the errors introduced by the grid snapping effect.

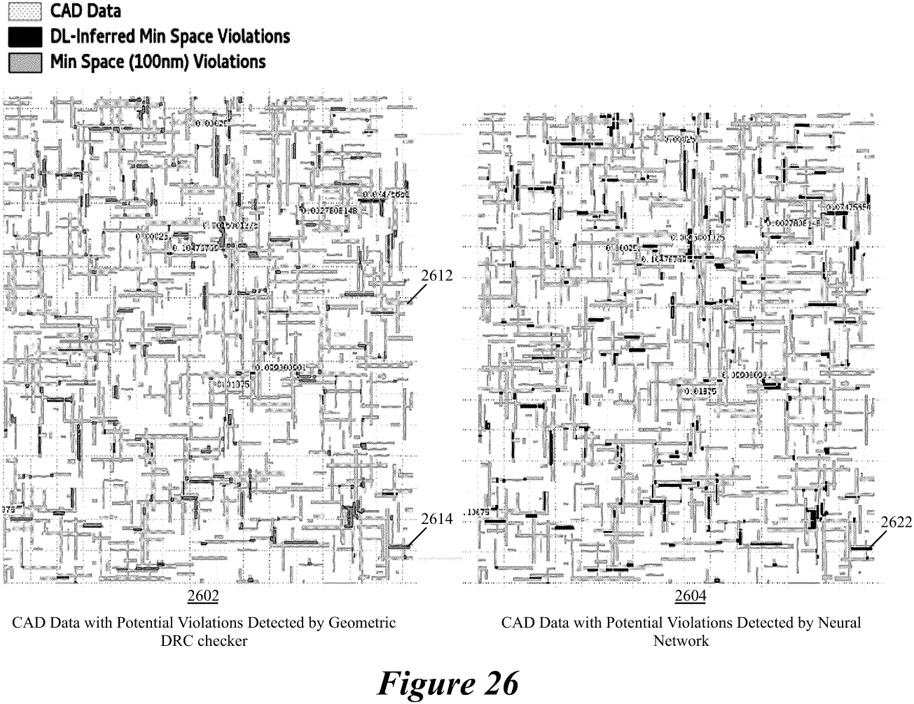

FIG. 26 illustrates examples of a ground truth (left) and deep learning-inferred (right) DRC marker violations for a 100 nm-minimum spacing rule. The design rule is set to a 100 nm-minimum spacing between design shapes for a rectilinear design style. The figure shows two images 2602 and 2604 obtained from a geometrical layout editing tool. On each of these images, there are two sets of shapes that are drawn either in a lighter shade or darker shade. On the left image 2602 (i.e., the image showing the CAD data along with the DRC violations identified by the geometric DRC checker), the lighter shade shapes represent the CAD objects while the darker shade shapes represent the violation markers identified by the geometric DRC checker. On the right image 2604 (i.e., the image showing the CAD data along with the DRC violations identified by the trained neural network), the lighter shade shapes represent the CAD objects while the darker shade shapes represent the violation markers identified by the trained neural network.

In both images, the lighter shade shapes 2612 (e.g., displayed as orange on a display screen in some embodiments) represent the CAD data that is the same in both images. The left image 2602 contains ground truth DRC violation markers 2614, which appear as darker shade shapes (e.g., displayed as blue on a display screen in some embodiments). These markers 2614 are obtained using a geometry-based DRC engine. The right image 2604 is reconstructed from the trained neural network output. This image 2604 contains predicted DRC violation markers 2622, which appear as darker shade shapes (e.g., displayed as red on a display screen in some embodiments). At the high-altitude zoom level shown in the figure, both images 2602 and 2604 appear essentially identical with the DRC markers 2614 and 2622 appearing at the same locations in both images.

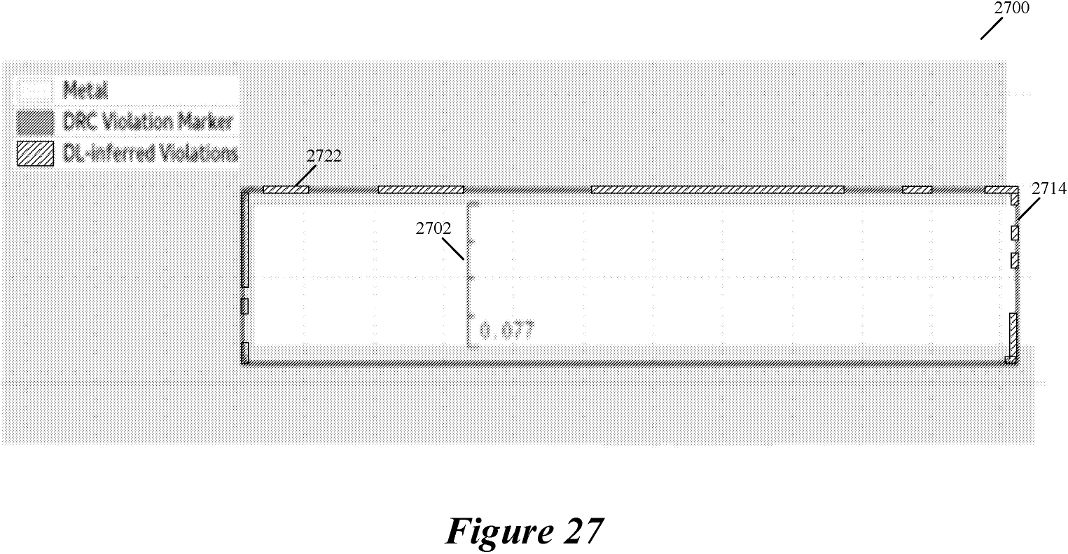

FIG. 27 illustrates an example of one of the marker locations at a lower-altitude zoom level 2700. As shown, the ground truth marker 2714 (e.g., displayed as blue on a display screen in some embodiments) and deep learning-inferred violation marker 2722 (appearing as right-to-left cross hatching in the figure and displayed as red on a display screen in some embodiments) both appear as rectangles and are still virtually indistinguishable. A ruler 2702 has been placed between the two edges which are found to be in violation of the 100 nm-minimum spacing rule, and both edges are contained within both the ground truth and the deep learning-inferred violation markers 2714 and 2722.

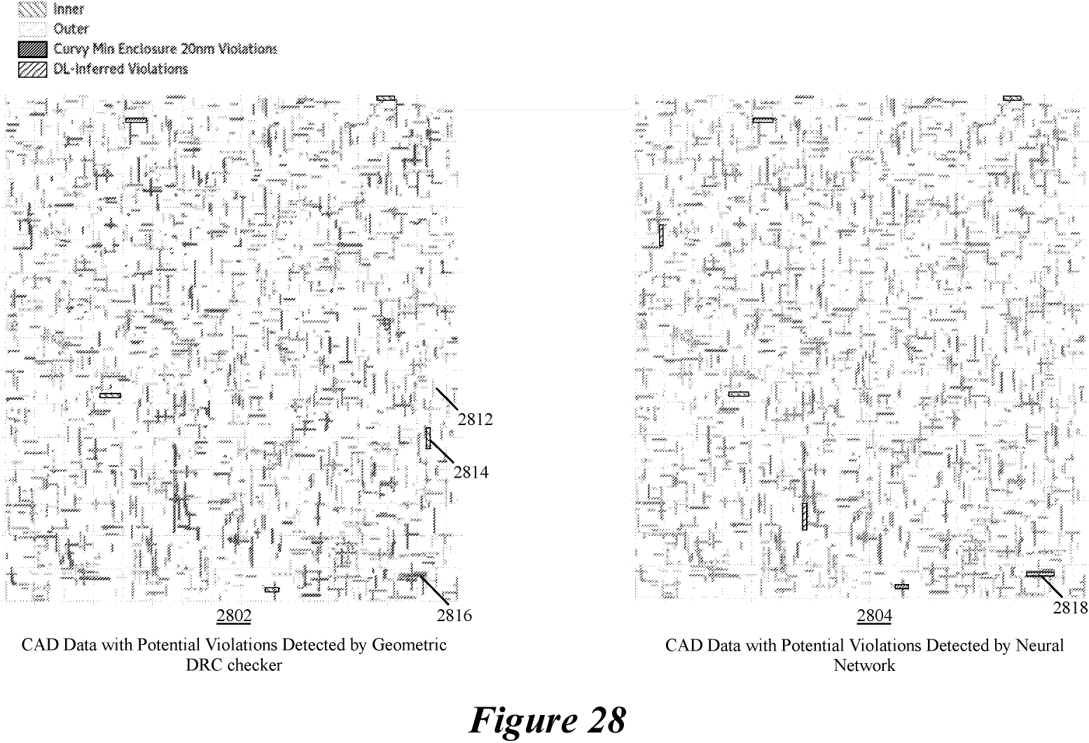

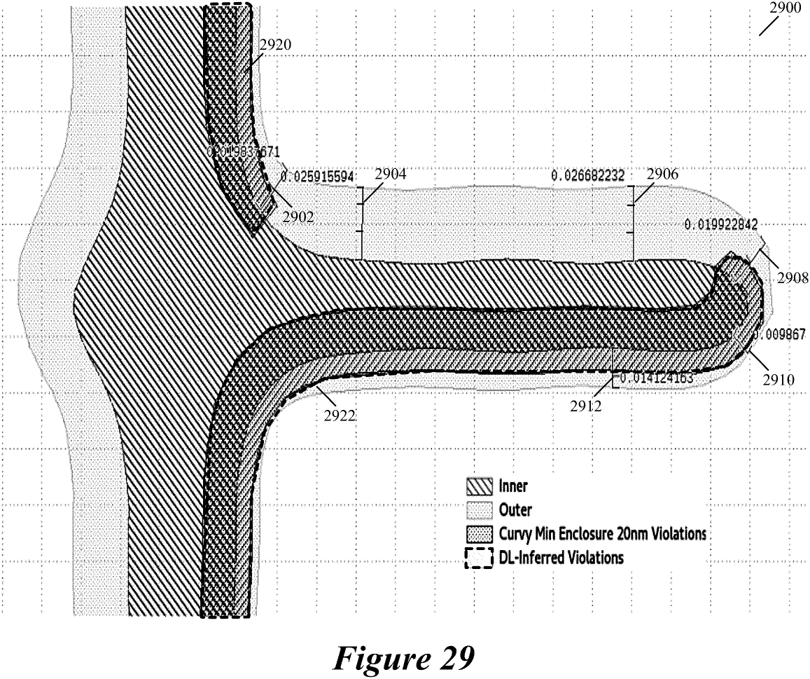

FIG. 28 illustrates an example of a ground truth and deep learning-inferred DRC marker violations for 20 nm-minimum enclosure rule on curvilinear data obtained from a geometrical layout editing tool. The left image 2802 represents the ground truth results while the right image 2804 represents the deep learning-inferred results. In this figure, there are three types of shapes drawn on each side in different shades. The left image 2802 includes the CAD data for the inner and outer layers, and the DRC violations that are identified by the geometric DRC checker. The right image 2804 includes the CAD data for the inner and outer layers, and the DRC violations that are identified by the trained neural network. Given the large number of shapes, a few of them are shown with cross hatching in the figure.

In both images, the lighter colored shapes 2812 (e.g., lighter grey shapes in the figure that are displayed as orange shapes on the display screen in some embodiments) represent the design data for the outer layer, which is the same in both left and right images 2802 and 2804. Also, in both images, the darker-colored shapes 2814 (some shown with left-to-right cross hatching) represent the design data for the inner layer. The design rule checks that the outer layer overlaps the inner layer with a minimum enclosure of 20 nm. Though hard to see at this high-altitude zoom level, the design data in both images is curvilinear, which will be appreciated in the zoomed-in (low-altitude zoom) images shown later. The left image 2802 contains ground truth DRC violation markers 2816 (e.g., darkest shade of grey shapes that are displayed as blue markers on a display screen in some embodiments). These markers 2816 are obtained using a geometry-based DRC engine. The right image 2804 is reconstructed from the trained neural network output. This image 2804 contains predicted DRC violation markers 2818 (some shown with right-to-left cross hatching), which in some embodiments are displayed as red markers on the display screen. At the high-altitude zoom level shown in the figure, both images 2802 and 2804 again appear essentially identical. DRC markers appear at the same locations in both images.

FIG. 29 illustrates an example of a low-altitude, zoomed-in view 2900, containing several ground truth violation markers. As shown, the curvilinearity is clear, and the locations where the violation markers have been created are identified. Regions of the inner layer that are not enclosed by the outer layer by 20 nm are highlighted by the markers 2920 and 2922. Again, rulers 2902-2912 have been added to aid in the visualization/understanding. In this example, the ground truth markers produced by a geometrical DRC engine coincide with the deep-learning inferred markers produced by the trained neural network, and the polygons for these markers essentially overlap.

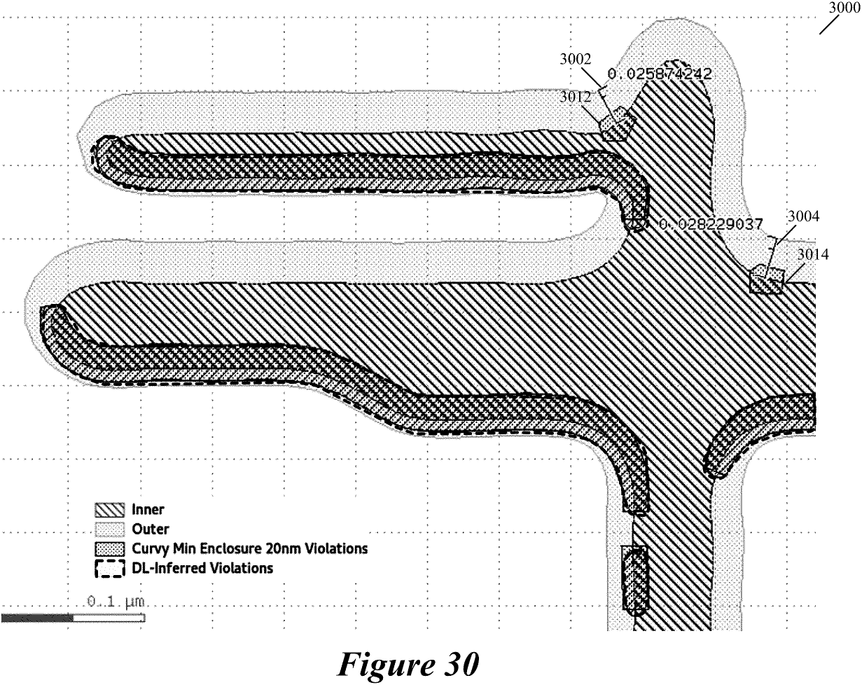

FIG. 30 illustrates an example of a different portion of the design 3000 containing both ground truth and deep learning-inferred markers. This figure shows that the geometric engine that produced the ground truth DRC markers (which are displayed in a first color, e.g., blue) has actually produced two markers 3012 and 3014 that escaped the filtering process. Rulers 3002 and 3004 have been roughly placed at the locations of these two markers 3012 and 3014 indicating that the enclosure amount is sufficiently large (i.e., these markers shouldn’t exist). However, no colored markers (e.g., red-colored markers) have been placed at these locations by the deep-learning approach. This shows the benefits of the deep-learning approach, avoiding spurious false positives that geometrical engines are susceptible to, due to grid snapping or other effects. In fact, for the full design shown in FIG. 28, 992 DRC violations were identified by the geometry-based engine compared with just 663 from the deep-learning based approach. The vast difference in violations were tiny false positives such as the two shown in FIG. 30.

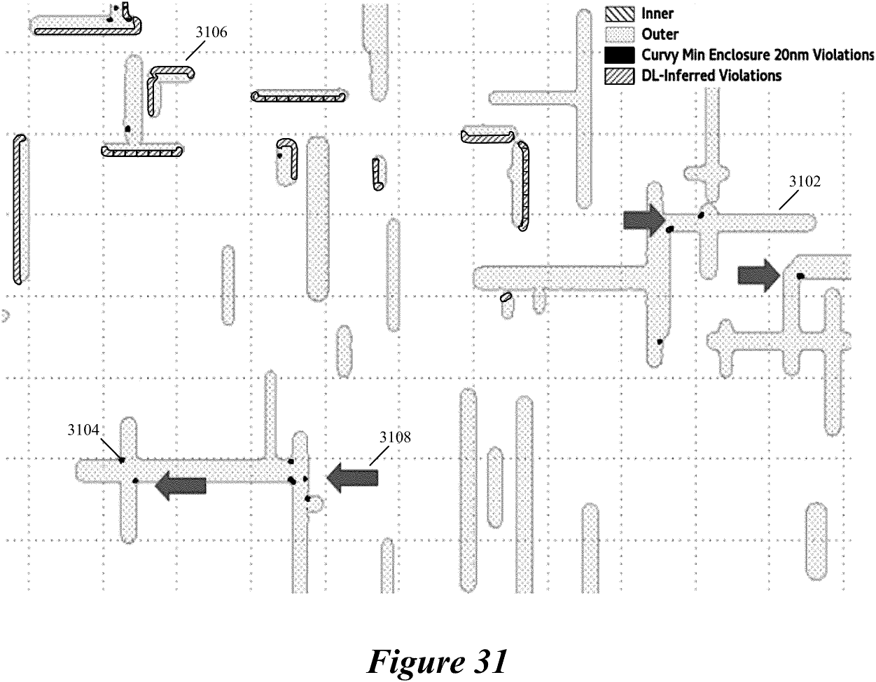

FIG. 31 illustrates an example of a portion of the design data with some clusters of geometric engine-produced false positives indicated, in which the ‘inner’ layer has been omitted for clarity. This figure presents an outer layer 3102 (appearing as light grey in this figure and are displayed in yellow or another light color on a display screen in some embodiments), several geometric engine-produced violations 3104 (appearing as dark grey in this figure and are displayed in blue on a display screen in some embodiments), and the deep learning-produced violations 3106 (appearing as right-to-left cross hatching in this figure and are displayed in red on a display screen in some embodiments). The deep learning-produced violations 3106 overlap with geometric engine-produced violations but a large number of small geometric engine-produced false positives are present. Some clusters of these are highlighted by the arrows 3108. The lack of such clusters in the deep-learning approach illustrates one of the significant benefits of the present invention.

Many of the above-described features and applications are implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Examples of computer readable media include, but are not limited to, CD-ROMs, flash drives, RAM chips, hard drives, EPROMs, etc. The computer readable media does not include carrier waves and electronic signals passing wirelessly or over wired connections.

In this specification, the term “software” is meant to include firmware residing in read-only memory or applications stored in magnetic storage, which can be read into memory for processing by a processor. Also, in some embodiments, multiple software inventions can be implemented as sub-parts of a larger program while remaining distinct software inventions. In some embodiments, multiple software inventions can also be implemented as separate programs. Finally, any combination of separate programs that together implement a software invention described here is within the scope of the invention. In some embodiments, the software programs, when installed to operate on one or more electronic systems, define one or more specific machine implementations that execute and perform the operations of the software programs.

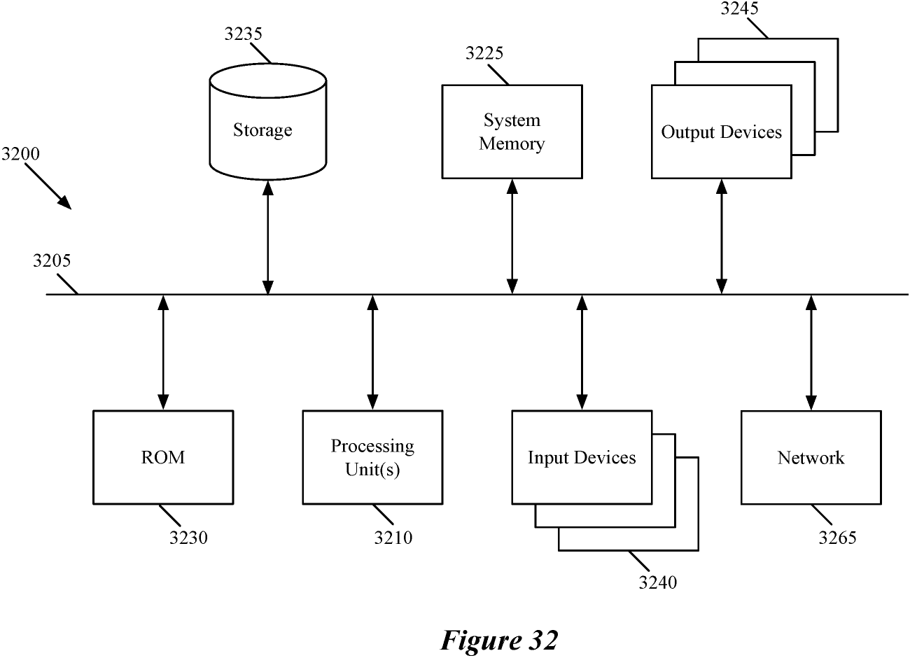

FIG. 32 conceptually illustrates an electronic system 3200 with which some embodiments of the invention are implemented. The electronic system 3200 may be a computer (e.g., a desktop computer, personal computer, tablet computer, server computer, mainframe, a blade computer etc.), phone, PDA, or any other sort of electronic device. As shown, the electronic system includes various types of computer readable media and interfaces for various other types of computer readable media. Specifically, the electronic system 3200 includes a bus 3205, processing unit(s) 3210, a system memory 3225, a read-only memory 3230, a permanent storage device 3235, input devices 3240, and output devices 3245.

The bus 3205 collectively represents all system, peripheral, and chipset buses that communicatively connect the numerous internal devices of the electronic system 3200. For instance, the bus 3205 communicatively connects the processing unit(s) 3210 with the read-only memory (ROM) 3230, the system memory 3225, and the permanent storage device 3235. From these various memory units, the processing unit(s) 3210 retrieve instructions to execute and data to process in order to execute the processes of the invention. The processing unit(s) may be a single processor or a multi-core processor in different embodiments.

The ROM 3230 stores static data and instructions that are needed by the processing unit(s) 3210 and other modules of the electronic system. The permanent storage device 3235, on the other hand, is a read-and-write memory device. This device is a non-volatile memory unit that stores instructions and data even when the electronic system 3200 is off. Some embodiments of the invention use a mass-storage device (such as a magnetic or optical disk and its corresponding disk drive) as the permanent storage device 3235.

Other embodiments use a removable storage device (such as a floppy disk, flash drive, etc.) as the permanent storage device. Like the permanent storage device 3235, the system memory 3225 is a read-and-write memory device. However, unlike storage device 3235, the system memory is a volatile read-and-write memory, such a random access memory. The system memory stores some of the instructions and data that the processor needs at runtime. In some embodiments, the invention’s processes are stored in the system memory 3225, the permanent storage device 3235, and/or the read-only memory 3230. From these various memory units, the processing unit(s) 3210 retrieve instructions to execute and data to process in order to execute the processes of some embodiments.

The bus 3205 also connects to the input and output devices 3240 and 3245. The input devices enable the user to communicate information and select commands to the electronic system. The input devices 3240 include alphanumeric keyboards and pointing devices (also called “cursor control devices”). The output devices 3245 display images generated by the electronic system. The output devices include printers and display devices, such as cathode ray tubes (CRT) or liquid crystal displays (LCD). Some embodiments include devices such as a touchscreen that function as both input and output devices.

Finally, as shown in FIG. 32, bus 3205 also couples electronic system 3200 to a network 3265 through a network adapter (not shown). In this manner, the computer can be a part of a network of computers (such as a local area network (“LAN”), a wide area network (“WAN”), or an Intranet, or a network of networks, such as the Internet. Any or all components of electronic system 3200 may be used in conjunction with the invention.

Some embodiments include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, read-only and recordable Blu-Ray® discs, ultra density optical discs, any other optical or magnetic media, and floppy disks. The computer-readable media may store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some embodiments are performed by one or more integrated circuits, such as application specific integrated circuits (ASICs) or field programmable gate arrays (FPGAs). In some embodiments, such integrated circuits execute instructions that are stored on the circuit itself.

As used in this specification, the terms “computer”, “server”, “processor”, and “memory” all refer to electronic or other technological devices. These terms exclude people or groups of people. For the purposes of the specification, the terms display or displaying means displaying on an electronic device. As used in this specification, the terms “computer readable medium,” “computer readable media,” and “machine readable medium” are entirely restricted to tangible, physical objects that store information in a form that is readable by a computer. These terms exclude any wireless signals, wired download signals, and any other ephemeral or transitory signals.

While the invention has been described with reference to numerous specific details, one of ordinary skill in the art will recognize that the invention can be embodied in other specific forms without departing from the spirit of the invention. For instance, a number of the figures conceptually illustrate processes. The specific operations of these processes may not be performed in the exact order shown and described. The specific operations may not be performed in one continuous series of operations, and different specific operations may be performed in different embodiments. Furthermore, the process could be implemented using several sub-processes, or as part of a larger macro process. Therefore, one of ordinary skill in the art would understand that the invention is not to be limited by the foregoing illustrative details, but rather is to be defined by the appended claims.

1. A method for performing design rule checking (DRC) on a design comprising a plurality of shapes, the method comprising:
receiving a first description of the design in a first non-pixelized format;
producing, from the first description, a second description of the design in a second pixelized format;
using the second description to provide input to a machine-trained network to process in order to identify a DRC violation in the design; and
based on output produced by the machine-trained network, identifying DRC violations in the design.

2. The method of claim 1 wherein the DRC violations are initially expressed in a pixel-based format, the method further comprising generating, for the identified DRC violations that are specified in the pixel-based format, contoured shapes to display with the design, and displaying the design with the contoured shapes in order to identify locations in the design that have DRC violations.

3. The method of claim 2, wherein the contoured shapes are displayed along with the design by a geometry-based design editing or visualization tool.

4. The method of claim 1, wherein the machine-trained network is a neural network.

5. The method of claim 1, wherein the shapes comprise rectilinear shapes and curvilinear shapes.

6. The method of claim 5, wherein each rectilinear shape is formed by Manhattan edges, each curvilinear shape is formed by at least one curvilinear edge, and the shapes further comprise shapes with at least one non-Manhattan rectilinear edge that has a 45-degree angle or another angle other than 0, 45, or 90.

7. The method of claim 1, wherein said producing comprises using the first description to rasterize the design to obtain the second pixelized format in which pixel values are used to describe the design.

8. The method of claim 7, wherein the first description comprises a description of shapes as polygons.

9. The method of claim 1, wherein the machine-trained network implements a DRC checking process.

10. The method of claim 1, wherein the machine-trained network partially implements a DRC checking process along with a pixel-based process.

11. The method of 10, wherein the pixel-based process comprises a morphological image-processing process.

12. A non-transitory machine-readable medium storing a program, which when executed by at least one processing unit of a computer, performs design rule checking (DRC) on a design comprising a plurality of shapes, the program comprising sets of instructions for:
receiving a first description of the design in a first non-pixelized format;
producing, from the first description, a second description of the design in a second pixelized format;
using the second description to provide input to a machine-trained network to process in order to identify a DRC violation in the design; and
based on output produced by the machine-trained network, identifying DRC violations in the design.

13. The non-transitory machine-readable medium of claim 12 wherein the DRC violations are initially expressed in a pixel-based format, the program further comprising a set of instructions for generating, for the identified DRC violations that are specified in the pixel-based format, contoured shapes to display with the design, and displaying the design with the contoured shapes in order to identify locations in the design that have DRC violations.

14. The non-transitory machine-readable medium of claim 13, wherein the contoured shapes are displayed along with the design by a geometry-based design editing or visualization tool.

15. The non-transitory machine-readable medium of claim 12, wherein the machine-trained network is a neural network.

16. The non-transitory machine-readable medium of claim 12, wherein the shapes comprise rectilinear shapes and curvilinear shapes.

17. The non-transitory machine-readable medium of claim 16, wherein each rectilinear shape is formed by Manhattan edges, each curvilinear shape is formed by at least one curvilinear edge, and the shapes further comprise shapes with at least one non-Manhattan rectilinear edge that has a 45-degree angle or another angle other than 0, 45 or 90.

18. The non-transitory machine-readable medium of 12, wherein the machine-trained network produces a single output representative of design violations for a single design rule.

19. The non-transitory machine-readable medium of 12, wherein the machine-trained network produces multiple outputs representative of design violations for multiple design rules.

20. The non-transitory machine-readable medium of claim 19, wherein the multiple design rules comprise at least two of DRC rule constraints regarding widths of shapes, DRC rule constraints regarding spacing between two shapes, and DRC rule constraints regarding an amount by which one shape encloses another.
